(19) United States
(12) Patent Application Publication
(10) Pub. No.: US 2016/0101979 A1
(43) Pub. Date: Apr. 14, 2016

(54) METHOD FOR PRODUCING MULTI-WALLED CARBON NANOTUBES, MULTI-WALLED CARBON NANOTUBES AND CARBON NANOTUBE POWDER

(71) Applicant: COVESTRO DEUTSCHLAND AG, Monheim Am Rhein (DE)

(72) Inventors: HEIKO HOCKE, Leverkusen (DE); Oliver Felix-Karl SHLÜTER, Leverkusen (DE); Volker MICHELE, Köln (DE); Leslaw MLECZKO, Dormagen (DE)

(21) Appl. No.: 14/894,140

(22) PCT Filed: Jun. 5, 2014
(86) PCT No.: PCT/EP2014/061722

§ 371 Date: Nov. 25, 2015

(30) Foreign Application Priority Data
Jun. 7, 2013 (DE) 102013210679.3

(51) Int. Cl. C01B 31/02; C23C 16/26; C23C 16/442

(52) U.S. Cl. CPC C01B 31/0253; C23C 16/442; C23C 16/26; C01B 2202/06; C01B 2202/36; C01P 2006/11

(57) ABSTRACT

The invention relates to temperature-stable rigid foams which can be cold formed and have a density of 0 to 100 kg/m (according to DIN 53420), an elongation at break (according to DIN 53430) of 12 to 35%, a percentage of open cells (according to DIN ISO 4590-86) of 51% to 98% and a storage module of the foam (according to DIN EN ISO 6721 B:1996-12) in the temperature range of 60 DEG to 190 DEG C of, on average, greater or equal 0.1 MPa, and to composite materials produced with said foams.

### CROSS-REFERENCE TO RELATED APPLICATIONS

This application is a national stage application (under 35 U.S.C. §371) of PCT/EP2014/061722, filed Jun. 5, 2013, which claims benefit of German Application No. 10 2013 210 679.3, filed Jun. 7, 2013, both of which are incorporated herein by reference in their entirety.

The invention relates to a process for producing multi-wall carbon nanotubes. The invention further relates to multi-wall carbon nanotubes and a carbon nanotube powder comprising these carbon nanotubes.

According to the prior art, carbon nanotubes are mainly cylindrical carbon tubes having a diameter in the range from 3 to 100 nm and a length which is a multiple of the diameter. These tubes consist of one or more layers of ordered carbon atoms and have a core having a different morphology. These carbon nanotubes are also referred to as, for example, “carbon fibrils” or “hollow carbon fibers”.

Carbon nanotubes have been known for a long time in the technical literature. Although Iijima (publication: S. Iijima, Nature 354, 56-58, 1991) is generally credited with being the discoverer of nanotubes, these materials, in particular fibrous graphite materials having a plurality of graphene layers, were known as early as the 1970s or early 1980s. Tates and Baker (GB 1469930A1, 1977 and EP 0056004A2, 1982) first describe the deposition of very fine fibrous carbon from the catalytic decomposition of hydrocarbons. However, the carbon filaments produced on the basis of short-chain hydrocarbons are not characterized in more detail in respect of their diameter.

The production of carbon nanotubes having diameters of less than 100 nm was described for the first time in EP 205 556B1 or WO 86/03455A1. These were produced using light (i.e. short- and medium-chain aliphatic or monocyclic or bicyclic aromatic) hydrocarbons and an iron-based catalyst over which the carbon carrier compounds are decomposed at a temperature above 800-900° C.

The methods known today for producing carbon nanotubes encompass electric arc processes, laser ablation processes and catalytic processes. In many of these processes, carbon black, amorphous carbon and fibers having large diameters are formed as by-products. Among catalytic processes, a distinction can be made between the deposition on introduced catalyst particles and deposition on metal sites which are formed in-situ and have diameters in the nanometer range (known as flow processes). In the production route via catalytic deposition of carbon from hydrocarbons which are gaseous under the reaction conditions (hereinafter referred to as CCVD; catalytic carbon vapor deposition), acetylene, methane, ethane, ethylene, butane, butene, butadiene, benzene and further carbon-containing starting materials have been mentioned as possible carbon donors.

The catalysts generally comprise metals, metal oxides or decomposable or reducible metal components. For example, Fe, Mo, Ni, V, Mn, Sn, Co, Cu and others are mentioned in the prior art as metals coming into question for catalysts. The individual metals used usually have, even alone, a tendency to catalyze the formation of nanotubes. However, according to the prior art, high yields of nanotubes and small proportions of amorphous carbons are advantageously achieved using metal catalysts which contain a combination of the abovementioned metals.

Particularly advantageous catalyst systems are, according to the prior art, based on combinations containing Fe or Ni. The formation of carbon nanotubes and the properties of the tubes formed depend in a complex way on the metal component or combination of metal components used as catalyst, the support material used and the interaction between catalyst and support, the feed gas and feed gas partial pressure, an addition of hydrogen or further gases, the reaction temperature and the residence time and the reactor used. Optimization is a particular challenge for an industrial process.

It should be noted that the metal component used in CCVD and referred to as catalyst is consumed during the course of the synthesis process. This consumption is attributable to deactivation of the metal component, e.g. as a result of deposition of carbon on the entire particle which leads to complete covering of the particle (known to those skilled in the art as “encapping”). Reactivation is generally not possible or not economically feasible. Only a maximum of a few grams of carbon nanotubes are often obtained per gram of catalyst, with the catalyst there comprising the totality of support and catalyst used. Owing to the indicated consumption of catalyst, a high yield of carbon nanotubes based on the catalyst used is an essential requirement which catalyst and process have to meet.

Typical structures of carbon nanotubes are those of the cylinder type (tubular structure). In the case of cylindrical structures, a distinction is made between single-wall carbon nanotubes (SWCNT) and multi-wall carbon nanotubes (MWCNT). Customary processes for producing them are, for example, electric arc processes (arc discharge), laser ablation, chemical deposition from the vapor phase (CVD process) and catalytic chemical deposition from the vapor phase (CCVD process). Cylindrical carbon tubes of this type can likewise be produced by an electric arc process. Iijima (Nature 354, 1991, 56-8) reports the formation by means of an electric arc process of carbon tubes which consist of two or more graphene layers which are rolled up to form a seamless closed cylinder and are nested within one another. Depending on the rolling-up vector, chiral and achiral arrangements of the carbon atoms along the longitudinal axis of the carbon fiber are possible.

Carbon nanotubes having a scroll structure in which one or more graphite layers consisting of two or more superposed graphite layers form a rolled structure can be produced by the process described in WO 2009/036877A2.

Further known structures of carbon nanotubes are described in a review (Milne et al. Encyclopedia of Nanoscience and Nanotechnology, 2003, Volume X, pp. 1-22; ISBN 1-58883-001-2). These structures are the “herringbone” structure, the cup-stacked structure and the stack structure and the bamboo structure, the platelet structure. Carbon nanofibers can likewise be produced by electrospinning of polyacrylonitrile and subsequent graphitization (Jo et al. Macromolecular Research, 2005, Volume 13, pp. 521-528).

With the increasing industrial and technological importance of carbon nanotubes, the requirements in respect of the nature and properties of the carbon nanotubes and also of the carbon nanotube powders composed of these have increased. Thus, there is firstly an increased demand for carbon nanotubes having a large diameter, i.e. having a plurality of graphene-like carbon layers. On the other hand, carbon nanotube powders having a prescribed diameter distribution are also wanted.

Furthermore, there is also general interest in doped carbon nanotubes in the case of which the properties of the tubes have been modified by doping of the carbon layers with foreign atoms. Doped carbon nanotubes are, for example, promising candidates for further miniaturized electronic circuits in the nanometer range.

Suitable and efficient production processes for the targeted production of carbon nanotubes having predetermined properties, in particular in respect of the diameter or the doping, are required.

In the prior art, Oberlin, Endo and Koyama described a way of producing cylindrical carbon nanotubes (Carbon 14, 1976, 133), in which aromatic hydrocarbons such as benzene are reacted over a metal catalyst at about 1100° C. in an entrained-flow reactor. Here, carbon nanotubes having a graphitic core are formed, but the core is covered with a coating of amorphous carbon. Targeted thickness growth in which the number of graphene-like layers of the carbon nanotubes is increased is not directly possible using this process.

A further process for producing carbon nanotubes is described in EP 0 205 556A1 (Hyperion Catalysis International), in which hydrocarbons are reacted over an iron-containing catalyst at temperatures above 800-1000° C. However, targeted growth of graphene-like layers on carbon nanotubes is also not possible by means of this process.

An article by Huang et al. (Small 2007, 3, 1735) describes noncatalytic layer growth on existing carbon nanotubes. In this process, the carbon nanotubes are heated to about 2000° C. by energy input by means of a flow of current between two gold electrodes, so that amorphous carbon is deposited on the nanotubes. Growth of graphene-like carbon layers on the nanotubes has also not been achieved by this process. In addition, this process is very complicated.

A process for producing doped carbon nanotubes is known from WO 2009/080204A1. In this process, catalytic growth of nitrogen-doped carbon nanotubes occurs in a fluidized bed. However, targeted doping of the carbon nanotubes, in particular different doping of the respective carbon layers, is not possible in this process.

In conclusion, it has therefore not hitherto been possible to deposit carbon graphitically on existing carbon nanotubes and thus increase the number of graphene-like layers of the carbon nanotubes by means of the above-described prior art. In particular, the diameter of the carbon nanotubes has not previously been able to be set in a targeted manner. Furthermore, the known processes also do not allow targeted doping of individual layers of the carbon nanotubes.

It is an object of the present invention to provide, inter alia, a process for producing carbon nanotubes, by means of which the number of graphene-like layers of carbon nanotubes can be increased directly. In particular, it is an object of the invention to provide a process by means of which the thickness growth of carbon nanotubes can be set in a targeted manner. It is also an object of the invention to provide, inter alia, a process by means of which carbon nanotubes having targeted doping in particular graphene-like layers can be produced. A further object of the invention is to provide corresponding carbon nanotubes and also a corresponding carbon nanotube powder.

These objects are, according to the invention, at least partly achieved by a process for producing multi-wall carbon nanotubes, which comprises the following steps:
initial charging of a substrate composed of carbon nanotubes in an agitated bed of a reactor,
introduction of a carbon-containing precursor into the agitated bed,
reaction of the precursor in the agitated bed under suitable process conditions which bring about graphitic deposition of carbon on the carbon nanotubes of the substrate,
discharge of the carbon nanotubes from the reactor.

In the context of the invention, it has been found that a process having these steps allows carbon to be deposited graphitically on the carbon nanotubes present in the substrate in such a way that additional graphene-like layers are formed around the individual carbon nanotubes. In contrast to the catalyst-dependent graphitic length growth known from the prior art, largely catalyst-independent thickness growth occurs according to the invention. In this way, the diameter of the carbon nanotubes can be increased in a targeted manner (known as epitactic growth).

### A BRIEF DESCRIPTION OF THE FIGURES

FIG. 1 shows an illustrative embodiment of the process of the invention using a fluidized-bed reactor,

FIG. 2 shows a further illustrative embodiment of the process of the invention using a rotary tube reactor,

FIG. 3a-e show illustrative embodiments of carbon nanotubes according to the invention which can, in particular, be produced by the process of the invention,

FIG. 4 shows a schematic depiction of a graphene structure with possible positions of doping atoms and

FIG. 5 shows a further illustrative embodiment of the process of the invention.

As substrate, it is in principle possible to use all types of carbon nanotubes. Examples of types of carbon nanotubes are: single-wall nanotubes having a single graphene-like layer, multi-wall nanotubes having a plurality of graphene-like layers; carbon nanotubes having a tubular structure, bamboo structure, rolled structure or scroll structure; capped carbon nanotubes in which at least one tubular graphene-like layer is closed off at its ends by fullerene hemispheres; or any possible combination of the abovementioned type and also carbon nanofibers.

The substrate is initially charged in an agitated bed of a reactor. A reactor having an agitated bed is in process engineering terms different from, in particular, a fixed-bed reactor or a reactor without a bed, for example an entrained-flow reactor. In the case of a reactor having a bed, the substrate is physically located above a support. In the case of a fixed-bed reactor, the substrate can, for example, be present in a boat open at the top, with the boat in this case serving as support. The subject is therefore essentially at rest during the process.

In contrast thereto, in the case of an agitated bed the substrate is mixed while carrying out the process. For this purpose, the substrate is preferably firstly applied to the surface of a support by means of which the substrate is kept in the reactor and spatially localized. During the process, the substrate is then mixed, for example, by agitation of the support or by flow of a gas stream through the substrate. Mixing of the substrate leads to improved heat transfer and mass transfer within the substrate and to a more efficient reaction.

In the case of reactor without a bed, for example entrained-flow reactors, the substrate is in contrast not localized spatially above a support but is instead moved through the reactor, for example together with a gas stream.

It has been found in experiments that the use of a reactor having an agitated bed enables graphitic carbon to be deposited on the carbon nanotubes. In contrast thereto, only deposition of a carbon layer, especially in the form of amorphous carbon, on the nanotubes was found in experiments using a fixed-bed reactor. As indicated at the outset, Oberlin, Endo and Koyama were also not able to observe graphitic deposition of carbon in an entrained-flow reactor, i.e. a reactor without a bed. It has accordingly been recognized according to the invention that the use of an agitated bed plays a critical role in the graphitic deposition of carbon on carbon nanotubes.

The substrate is preferably initially charged as powder, in particular as free-flowing powder. The powder flow rate of the powder in accordance with DIN EN ISO 6186 is preferably from 5 ml/s to 100 ml/s, in particular from 10 ml/s to 70 ml/s. In this way, good mixing of the substrate in the agitated bed is achieved during the process. The powder flow rate can be determined, for example, by means of a powder flow instrument from Karg-Industrietechnik (code No. 1012.000) model PM and a 15 mm nozzle in accordance with the standard ISO 6186.

To achieve a good yield, i.e. a high degree of deposition of graphitic carbon on the carbon nanotubes, the substrate can firstly be arranged with a bulk density in accordance with DIN EN ISO 60 of preferably from 20 to 500 kg/m′, more preferably from 20 to 450 kg/m³, in particular from 80 to 350 kg/m³, on the support of the reactor.

The surface area on the substrate used, measured as BET surface area in accordance with DIN ISO 9277, is preferably greater than 20 m²/g, more preferably greater than 100 m²/g, in particular greater than 200 m²/g. This makes a greater surface area available for graphitic deposition, so that the yield can be increased.

The carbon-containing precursor preferably contains or consists of an optionally substituted aliphatic, cyclic, heterocyclic, aromatic or heteroaromatic compound or a mixture thereof.

Here, aliphatic means an unbranched, branched and/or cyclic alkane, alkene or alkyne. The aliphatic molecules preferably have from about 1 to about 20, in particular from about 1 to about 12 and particularly preferably from about 2 to about 6, carbon atoms.

Practical experiments have shown that particularly good results are obtained when the carbon-containing precursor is an at least partially unsaturated or aromatic compound or the precursor contains such a compound or a mixture thereof.

Examples of partially unsaturated compounds are unbranched, branched and/or cyclic alkenes or alkynes, which can optionally be substituted.

The term “alkene” as used here refers to a hydrocarbon skeleton containing at least one carbon-carbon double band. Carbon containing precursors which can be used according to the invention are, for example, ethylene, propene, butene, butadiene, pentene, isoprene, hexene, 1-, 2- or 3-heptene, 1-, 2-, 3- or 4-octene, 1-nonene or 1-decene, with these optionally being able to be substituted, e.g. acrylonitrile.

The term “alkyne” as used here refers to a hydrocarbon skeleton containing at least one carbon-carbon triple bond. Carbon-containing precursors which can be used according to the invention are, for example, ethyne, propyne, butyne, pentyne, hexyne, 1-, 2- or 3-heptyne, 1-, 2-, 3- or 4-octyne, nonyne or decyne, with these optionally being able to be substituted.

Possible cyclic alkenes or alkynes are nonaromatic, monocyclic or polycyclic ring systems having, for example, from about 3 to about 10, preferably from about 5 to about 10, carbon atoms, which in the case of cycloalkenes contain at least one carbon-carbon double bond, in the case of cycloalkynes at least one carbon-carbon triple bond. Examples of monocyclic cycloalkenes are cyclopentene, cyclohexene, cycloheptene and the like. An example of a polycyclic alkene is norbornene.

The carbon-containing precursor can also contain an optionally substituted heterocyclic molecule or consist of the latter. Here, the term “heterocyclic” refers to a monocyclic or polycyclic ring system having from about 3 to about 10, preferably from about 5 to about 10, in particular from about 5 to about 6, carbon atoms, with one or more carbon atoms in the ring system being replaced by heteroatoms.

The term “heteroatom” as used here refers to one or more atoms selected from among oxygen, sulphur, nitrogen, boron, phosphorus or silicon, with the oxidized forms in each case being encompassed.

In a particularly preferred embodiment of the invention, the heterocyclic compounds used as carbon-containing precursors contain at least one carbon-carbon or carbon-heteroatom double bond.

The term “aromatic molecule” or “aromatic compound” as used here encompasses optionally substituted carbocyclic and heterocyclic compounds which contain a conjugated double bond system. Heterocyclic aromatics are also referred to as “heteroaromatics”. Examples of aromatic molecules according to the invention are optionally substituted monocyclic aromatic rings having from 0 to 3 heteroatoms selected independently from among O, N and S, or 8- to 12-membered aromatic bicyclic ring systems having from 0 to 5 heteroatoms, selected independently from among O, N and S. Carbon-containing precursors which can be used according to the invention are, for example, optionally substituted benzene, naphthalene, anthracene, pyridine, quinoline, isoquinoline, pyrazine, quinoxaline, acridine, pyrimidine, quinazoline, pyridazine, cinnoline, furan, benzofuran, isobenzofuran, pyrrole, indole, isoindole, thiophene, benzothiophene, imidazole, benzimidazole, purine, pyrazole, indazole, oxazole, benzoxazole, isoxazole, benzisoxazole, thiazole and/or benzothiazole.

When the expression “optionally substituted” is employed here, this means that the molecule or the compound can either be unsubstituted or bear a plurality of, preferably from 1 to 3, substituents. The substituents can be purely aliphatic or contain one or more heteroatoms. In a preferred embodiment, the substituents are selected from the group consisting of C₁-C₁₀-aliphatic, C₃-C₁₀-cycloaliphatic, C₆-C₁₀-aryl, 5- to 10-membered heteroaryl and 3- to 10-membered heterocyclyl, C₁-C₆-haloalkyl, C₁-C₁₀-alkoxy, halogen, NO₂, —OH, —CN, -sulfo, -phosphono and -silanyl.

Examples of carbon-containing precursors which have in practice achieved good to very good results are unsaturated hydrocarbons such as ethylene or acrylonitrile and aromatic molecules such as benzene or pyridine.

The use of a reactor having an agitated bed makes it possible to set process conditions under which carbon is deposited graphitically on the carbon nanotubes in the substrate. Graphitic deposition of carbon results, especially in contrast to the deposition of amorphous carbon, to formation of further graphene-like layers on the carbon nanotubes. These layers can, for example, have a tubular structure or else a scroll structure.

The parameters for the process conditions under which graphitic deposition occurs are partly dependent on the reactor used. As guides to typical process parameters, examples of process conditions under which graphitic deposition has been able to be observed are given below. The process conditions encompass, in particular, the important parameters of process temperature and agitation of the agitated bed. In the case of fluidized-bed reactors, the agitation of the bed is determined, for example, by the gas flow through the fluidized bed. Furthermore, the process time and also the type of precursor used can be important for the production of the carbon nanotubes.

After carrying out the process, the carbon nanotubes can be taken from the reactor. Owing to the graphene-like layers deposited on the carbon nanotubes during the process, the carbon nanotubes now have a greater average external diameter.

For the process conditions which bring about graphitic deposition, preference is given to setting a process temperature in the range from 850° C. to 1300° C., more preferably in the range from 900° C. to 1300° C., in particular from 950° C. to 1300° C. Measurements have shown that below a temperature of 850° C. no appreciable deposition of graphitic carbon occurs. Above 1300° C., the thermal stresses on the reactor become so great that it is possible to use only special reactor materials which would make the process expensive and uneconomical. The highest yields of the process were found experimentally in a preferred range from 950° C. to 1050° C.

In a preferred embodiment of the process, the proportion of active catalyst material which could bring about length growth of carbon nanotubes in the agitated bed during the process is less than 5000 ppm, preferably less than 1000 ppm, in particular less than 500 ppm. In this way, the thickness growth can be increased, i.e. the proportion of the carbon introduced as precursor which is deposited graphitically on the carbon nanotubes can be increased.

Catalysts which bring about length growth of carbon nanotubes are, in particular, used in the production of carbon nanotubes in known processes. For example, iron-, cobalt- or nickel-containing catalysts are frequently used for this purpose.

It has been found that the presence of such catalysts in the process described can reduce the thickness growth of the carbon nanotubes. This is presumably due to the carbon made available by the precursors being consumed for the length growth of the carbon nanotubes induced by the catalysts, so that sufficient carbon is no longer available for graphitic deposition and thus for thickness growth of the carbon nanotubes.

The amount of catalyst reported in parts per million (ppm) relates to the proportion by weight of the catalyst metal based on the total weight of the substrate. Furthermore, this figure is restricted to the catalyst particles which are actively available for catalysis in the substrate. Passivated catalyst particles, in particular catalyst particles enclosed by encapping, for example in the interior of catalyst nanotubes, are irrelevant for the present purposes and are therefore not taken into account in the figures given.

The low concentrations of the catalysts which are advantageous for the process can, in a further embodiment, be achieved by cleaned, in particular acid-cleaned, carbon nanotubes being used for the substrate. In the catalytic production of carbon nanotubes, residues of the catalyst used normally remain in the carbon nanotube powder produced. This is the case, for example, for commercially available carbon nanoatubes such as Baytubes® C 150 P. These catalyst residues can be largely removed from the catalyst nanotube powder by means of an acid wash, in particular using hydrochloric acid, so that acid-cleaned carbon nanotubes have only very low catalyst residue contents.

In a further embodiment of the process, the process conditions, in particular temperature, pressure and/or gas composition in the reactor, are selected so that the kinetic constant for thickness growth of the carbon nanotubes, i.e. for the graphitic deposition of carbon on the outer graphene layers of the carbon nanotubes, is greater than the kinetic constant for the length growth of the carbon nanotubes caused by catalyst constituents. The kinetic constants are preferably set via the process conditions in such a way that the ratio of the carbon consumed for thickness growth to the carbon consumed for length growth is greater than 1, preferably greater than 5, in particular greater than 10. At moderate temperatures, catalytic processes such as the length growth of the carbon nanotubes generally display a higher conversion than noncatalytic processes such as the thickness growth of the carbon nanotubes. The abovementioned ratios can therefore be achieved, in particular, at very high process temperatures, preferably at process temperatures of more than 900° C., in particular at least 950° C.

In a further illustrative embodiment of the process of the invention, a fluidized bed of a fluidized-bed reactor is used as agitated bed. In a fluidized-bed reactor, the substrate is placed on a support, in particular a support plate. A gas stream is passed through nozzle openings provided in the support into the substrate, so that the substrate and the gas stream form a fluidized bed. The fluidized bed displays liquid-like behavior in which the individual particles of the substrate are mixed in the gas stream. Apart from the good mixing of the substrate, good heat transfer and mass transfer are also achieved in the fluidized bed, so that essentially homogeneous process conditions are present in the fluidized bed. This promotes uniform graphitic deposition of carbon on the carbon nanotubes. In experiments, correspondingly high yields were obtained using the fluidized-bed reactor.

As fluidized-bed reactor, it is possible to use, for example, a fused silica fluidized-bed reactor in which the reactor is formed essentially by a fused silica housing, for example a fused silica tube.

In an alternative embodiment of the process, the agitated bed can also be provided by means of a rotary tube reactor. A rotary tube reactor has a reactor tube whose longitudinal axis is aligned at a small angle of, for example, 1-5° to the horizontal. The reactor tube is mounted so as to be rotatable about its longitudinal axis and is able to be driven so as to rotate about this axis. To carry out the process, the substrate is firstly applied to the interior surface of the reactor tube. The reactor tube is subsequently rotated about its longitudinal axis while a carbon-containing precursor is introduced into the reactor tube.

In a further embodiment of the process in which the fluidized bed of a fluidized-bed reactor is used as agitated bed, for the process conditions which bring about graphitic deposition, gas flow through the fluidized bed is set in such a way that stable fluidization is ensured. Good yields have been found experimentally when using this gas flow range in the graphitic deposition of the carbon. To control the yield and the process itself, it is also possible to use gas mixtures, e.g. a mixture of inert carrier gas with the carbon-containing precursor.

For the purposes of the present invention, stable fluidization means that the gas flow has a velocity which is greater than or equal to the minimum fluidization velocity. As regards the determination of the minimum fluidization velocity, reference may be made to WO 2007/118668A2 whose contents are incorporated by reference into the present description. In particular, reference is made to the formula (1) on page 7 of WO 2007/118668A2 for determining the minimum fluidization velocity.

In a further embodiment of the process, a precursor input into the reactor of from 0.0001 to 1 g, preferably from 0.001 to 0.2 g, in particular from 0.005 to 0.1 g, per gram of substrate and per minute is set for the process conditions which bring about the graphitic deposition. This precursor input has been found experimentally to be advantageous for a high yield from the process. At a lower precursor input, too little carbon is available for optimal graphitic deposition. At a higher precursor input, part of the precursor remains unreacted or even deposited in nongraphitic form, so that the results of the process are impaired.

The process can be carried out continuously, pseudocontinuously or batchwise. In a continuous process, carbon nanotubes as substrate are fed continuously into the fluidized-bed reactor and/or processed carbon nanotubes are continuously taken off. In a batch process, the process is carried out using successive batches. For a batch, a substrate is initially placed in the reactor and the substrate which has been converted preferably completely into the product is essentially entirely taken out from the fluidized-bed reactor at the end of the process. In a pseudocontinuous process, only a certain part of the product is taken from the fluidized-bed reactor at the end of a process operation and a corresponding amount of the substrate is replenished.

In a further embodiment of the process, in particular in the case of a quasi-continuous or batch process, a process time in the range from 10 to 600 minutes, preferably from 10 to 120 minutes, is set.

The process time is preferably set so that the diameter distribution of the carbon nanotubes produced have a diameter ratio D90/D10 of less than 4, preferably less than 3, after the end of the process. The process time is more preferably set so that the diameter ratio D90/D10 of the carbon nanotubes produced compared to the corresponding diameter ratio of the starting material, i.e. the carbon nanotubes initially charged as substrate, has been reduced by at least 20%, preferably by at least 30%, in particular by at least 40%. It has been found that graphitic deposition of the carbon occurs preferentially on carbon nanotubes which have a below-average diameter relative to the substrate since these have a greater surface area-to-mass ratio and therefore a greater reaction area for the deposition of carbon. Due to this effect, the diameter of the relatively thin carbon nanotubes on average increases more quickly than the diameter of the thicker carbon nanotubes, so that as a result the diameter distribution of the carbon nanotubes becomes narrower.

The diameter value D90 or D10 means that 90% or 10%, respectively, of the carbon nanotubes have a diameter smaller than this diameter. The diameter ratio D90/D10 corresponds to the ratio of D90 to D10.

The carbon-containing precursor contains, according to a further embodiment of the process, an at least partially unsaturated or aromatic compound or consists thereof. In experiments, it has been found that such molecules, for example benzene or ethylene, bring about graphitic deposition of carbon. A carbon-carbon or carbon-heteroatom double bond or in particular an aromatic ring accordingly promote graphitic deposition.

The production of carbon nanotubes having individual doped grapheme-like layers can, in a further preferred embodiment of the process, be achieved by the carbon-containing precursor used containing or consisting of a compound comprising carbon and at least one heteroatom from the group consisting of nitrogen, boron, phosphorus and silicon. As an alternative, the carbon-containing precursor can also contain at least two compounds of which at least one comprises carbon and of which at least another comprises an element from the group consisting of nitrogen, boron, phosphorus and silicon. In place of oxygen, nitrogen, boron, phosphorus or silicon, other foreign atoms suitable for doping are also possible in the above-described embodiment.

In this embodiment, graphene-like layers which have doping corresponding to the precursor can be deposited in a targeted manner on the carbon nanotubes in the substrate. In this way, it is possible to produce, for example, carbon nanotubes which have various layers having different doping or both doped and undoped layers.

In the process, it is possible, for example, for a first precursor to be introduced into the agitated bed in a first step and a second precursor to be introduced into the agitated bed in a second step carried out subsequently. In this way, different graphene-like layers, in particular doped and undoped layers or differently doped layers, can be deposited in succession on the carbon nanotubes. This opens up the possibility of influencing the properties of carbon nanotubes in a targeted manner by individual doping and thus providing tailored carbon nanotubes. For example, carbon nanotubes having layers which alternate in terms of their doping can be produced by alternating introduction of various precursors.

The object of the invention in respect of a multi-wall carbon nanotube having at least one first graphene-like layer and a second graphene-like layer, with the second layer being located outside the first layer in the cross section of the carbon nanotube, is achieved according to the invention by one of the two layers having a first doping and the other of the two layers having a second, different doping or being undoped. For example, the second layer, i.e. the outer layer, can have a first doping while the first layer, i.e. the inner layer, is undoped or has a second, different doping. As an alternative, the first layer, i.e. the inner layer, can have a first doping while the second layer i.e. the outer layer, is undoped or has a second, different doping.

The targeted doping of individual graphene-like layers enables the properties of the carbon nanotubes to be tailored. This results in new fields of use for the carbon nanotubes. The targeted setting of the electrical or electronic properties makes it possible to use the carbon nanotubes as components in electronic circuits. Targeted setting of the chemical properties makes it possible to use the carbon nanotubes as catalysts. For this purpose, the carbon nanotubes can be functionalized in a targeted manner by the doping. Furthermore, the compatibility of the carbon nanotubes with other materials can be adjusted by the doping, for example for use in composites. A further possible use of the carbon nanotubes having targeted doping is in the field of electrode materials and lithium ion batteries. In particular, use of the carbon nanotubes as conductivity additive or anode material is possible.

The above-described carbon nanotubes are preferably produced by one of the processes described above. Conversely, the above-described processes can preferably be used for producing such carbon nanotubes.

The second layer of the carbon nanotube is arranged outside the first layer in cross section. For the purposes of the present invention, such an arrangement means that the first layer is a layer located further inside relative to the cross section of the carbon nanotube and the second layer is a layer located further outside, i.e. a layer further from the midpoint of the cross section.

The first and second layers can be located directly on top of one another. As an alternative, further layers can also be arranged between the first layer and the second layer.

The first and second layers can, for example, each have a tubular structure, so that each of the two layers has a tubular shape with the second layer enclosing the first layer. As an alternative, the layers can also be present in a scroll structure in which a plurality of superposed, graphene-like layers are rolled up to form the structure. An outer graphene-like layer of this roll can then be considered to be the second layer and an inner graphene-like layer can be considered to be the first layer. Furthermore, combinations, for example with tubular inner layers and outer layers of the scroll type or vice versa, are also possible.

For the purposes of the present invention, doping means that the otherwise graphene-like structure of a layer has foreign atoms in addition to the carbon atoms, preferably at least 1.5 at. %, more preferably at least 2 at. %, even more preferably at least 5 at. %, in particular at least 10 at. %, of foreign atoms. These can, for example, be arranged in place of carbon atoms at lattice sites or defects of the graphene lattice. For the purposes of the present invention, an undoped layer is a graphene-like layer which has not been deliberately doped by foreign atoms, so that the defects within this layer are in the natural defect range, i.e. in particular in the range ≦1 at. %, in particular ≦0.5 at. %.

In a preferred embodiment of the carbon nanotube, one of the layers is doped with nitrogen, boron, phosphorus or silicon or a combination thereof. The properties, in particular the electrical properties, of the layers can be altered in a targeted manner by doping with one or more types of these foreign atoms. The other of the two layers is in this case preferably undoped or is doped with a different type of foreign atom from the group consisting of nitrogen, boron, phosphorus and silicon.

A next preferred embodiment of the carbon nanotube is characterized in that the carbon nanotube has a third graphene-like layer, in that the second layer is arranged within the third layer in the cross section of the carbon nanotube and in that the first and third layers are undoped. This gives a carbon nanotube which has alternating layers and in which a doped layer is surrounded by two undoped layers. Such a carbon nanotube can be produced, for example, by one of the above-described processes by introducing various precursors into the agitated bed at time intervals.

The object of the invention is also achieved by a carbon nanotube powder which contains the above-described carbon nanotubes.

The carbon nanotubes of the carbon nanotube powder preferably have an average diameter of from 3 to 100 nm, more preferably from 5 to 50 nm, in particular from 10 to 25 nm. This diameter range corresponds to many industrial requirements and can readily be achieved by means of the invention.

In further embodiment, the diameter distribution of the carbon nanotubes after carrying out the process has a diameter ratio of D90/D10 of less than 4, preferably less than 3. In a further embodiment, the diameter distribution of the carbon nanotubes after carrying out the process has a diameter ratio which is at least 20% lower, preferably at least 30% lower, in particular at least 40% lower, than the diameter ratio of the starting material initially charged as substrate.

These embodiments are advantageous since new applications of carbon nanotubes frequently require a predetermined, generally narrow, diameter distribution. This can be achieved by means of the carbon nanotubes of the invention and the corresponding carbon nanotube powder. Production of these can, for example, be carried out as described above for the process by appropriate setting of the process time.

The carbon nanotube powder preferably has a purity of at least 90%, preferably at least 95%, in particular at least 97%. For the present purposes, the purity is the proportion in percent by weight of carbon nanotubes in the powder relative to other constituents such as, in particular, amorphous carbon and inorganic metal oxides. It has been found that carbon nanotube powders having a high purity can be produced by means of the present invention.

As a measure of the high proportion of graphitic carbon in the carbon nanotube powder, it is possible to employ the area ratio D/G of the D band to the G band in the Raman spectrum. The D band (disorder band) is at about 1300 cm⁻¹ and the G band (graphite band) is at about 1588 cm⁻¹. To calculate the area ratio D/G, the integrals of the Raman spectrum over the D band and over the G band are determined and the ratio is then calculated. The carbon nanotube powder preferably displays a D/G ratio of less than 1.5, preferably less than 1, in the Raman spectrum.

Further features and advantages of the present invention and also specific examples of carrying out the process of the invention can be derived from the following description of a number of illustrative embodiments and also experimental results. Here, reference will also be made to the accompanying drawings.

In the drawings,

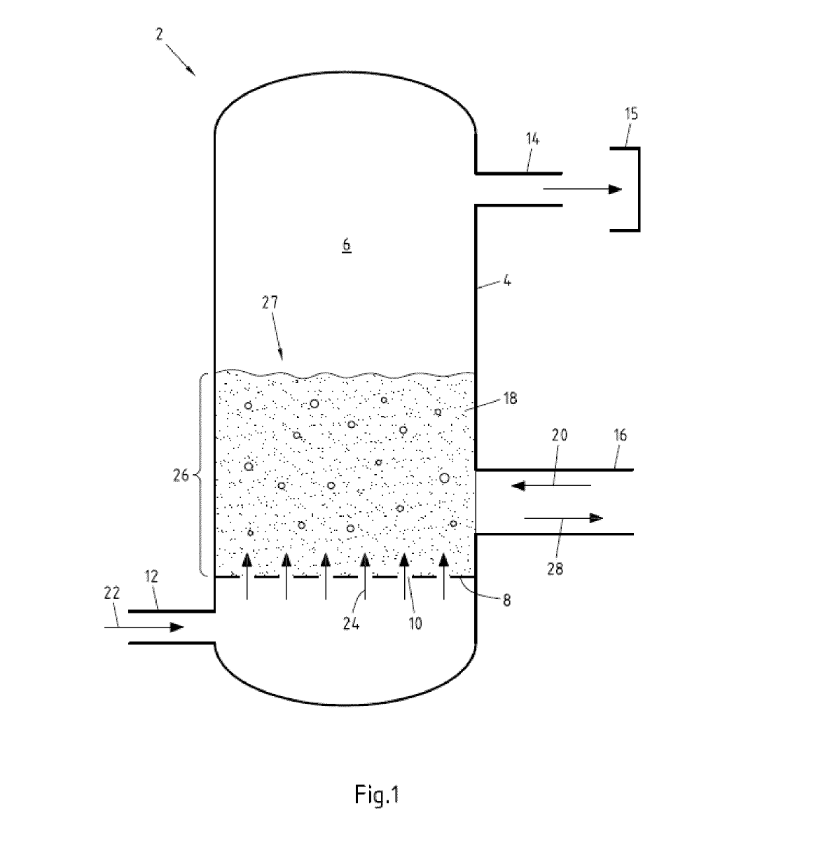

FIG. 1 shows an illustrative embodiment of the process of the invention using a fluidized-bed reactor,

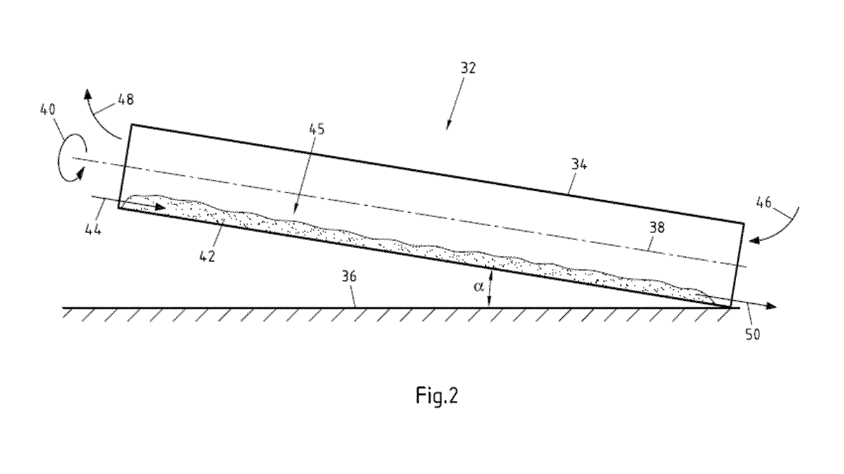

FIG. 2 shows a further illustrative embodiment of the process of the invention using a rotary tube reactor,

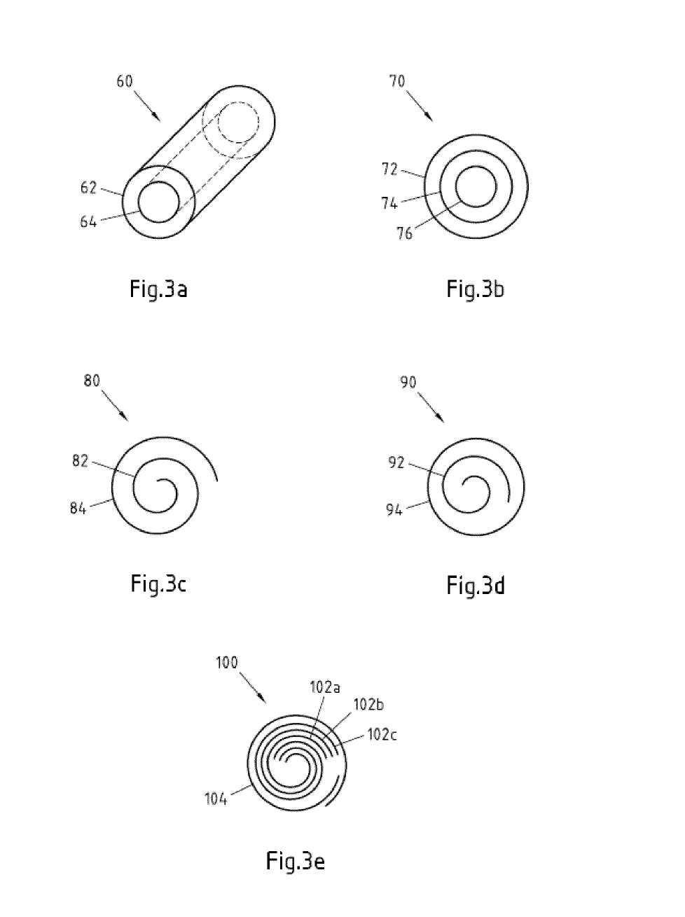

FIG. 3a-e show illustrative embodiments of carbon nanotubes according to the invention which can, in particular, be produced by the process of the invention,

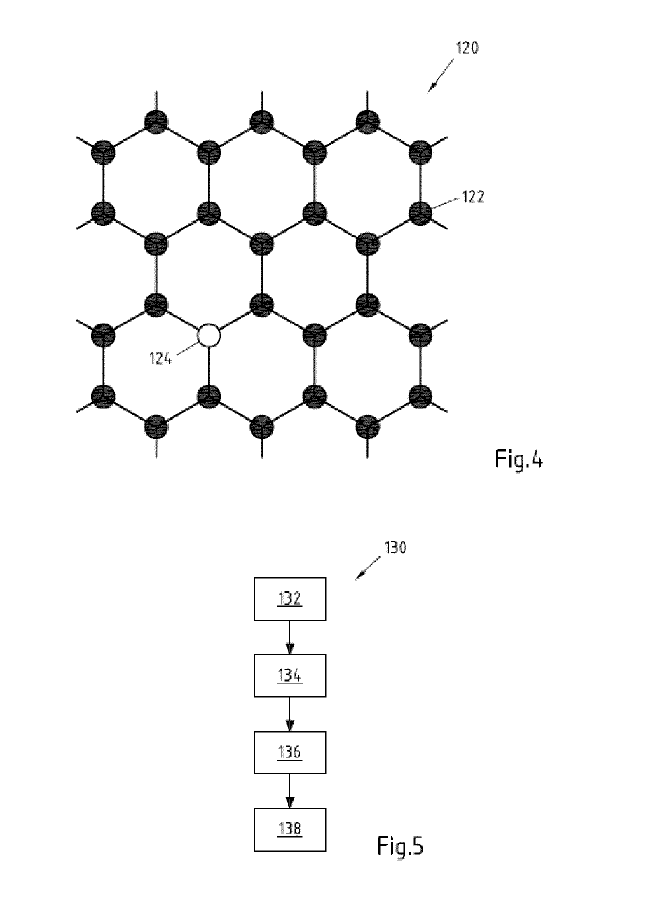

FIG. 4 shows a schematic depiction of a graphene structure with possible positions of doping atoms and

FIG. 5 shows a further illustrative embodiment of the process of the invention.

FIG. 1 shows an illustrative embodiment of the process of the invention using a fluidized-bed reactor. The fluidized-bed reactor 2 has a reactor housing 4 which surrounds a reactor space 6. The reactor housing 4 is in the present case configured as a fused silica tube closed at both ends. The reactor space 6 is bounded at the bottom by a support plate 8 which has a plurality of nozzle openings 10. The reactor 2 additionally has a gas inlet 12 and a gas outlet 14 which are arranged so that a gas can flow via the gas inlet 12 through the nozzle openings 10 into the reactor space 6 and leave the latter again through the gas outlet 14. A condensation trap 15 can be provided at the gas outlet 14 in order to be able to determine the amount of precursor material which has not been reacted during the process.

Instead of or in addition to a condensation trap 15, appropriate devices for offgas after-treatment, for example offgas burners, filters, offgas scrubbers and the like, can also be provided at this position.

At the beginning of the process, a pulverulent substrate 18 composed of carbon nanotubes is introduced as starting material through a conduit 16 provided for this purpose into the reactor space 6 (see arrow 20) and applied with a bulk density of, for example, from 20 to 450 kg/m³ to the support plate 8.

A process gas such as nitrogen is introduced via the gas inlet 12 into the reactor 2 (cf. arrow 22) and is conveyed through the nozzle openings 10 (cf. arrow 24) into the substrate 18. The process gas flowing through the nozzle openings 10 together with the substrate 18 forms a fluidized bed 26 in which the mixture of the process gas and the substrate is present in a fluidizing, i.e. a liquid-like, state. Intensive mixing of the substrate and good heat equilibration occur in the fluidized bed 26. As a result of the fluidized bed 26, the substrate in the reactor 2 is present in an agitated bed 27.

A process temperature in the range from 950° C. to 1300° C., in particular 1000° C., is set within the reactor space 6, in particular within the fluidized bed 26, by means of heating means provided for this purpose (not shown). For example, the process gas can be heated to the desired temperature by the heating means before introduction into the fluidized bed. The heat energy then stored in the process gas is transferred to the substrate in the fluidized bed.

A carbon-containing precursor, in particular ethylene or benzene, is then introduced into the fluidized bed 26. This can occur together with the process gas via the inlet 12 or through a separate inlet. When a gaseous precursor is used, this can simultaneously also be used as process gas.

Within the reactor space 6, the precursor reacts in the fluidized bed 26 and, when the process conditions are appropriately set, leads to deposition of graphitic carbon on the carbon nanotubes.

After the end of the process, the process product, i.e. the carbon nanotubes of the substrate 18 which have been altered by deposition of graphitic carbon, are taken off again from the fluidized-bed reactor 2 through the conduit 16 (arrow 28). The carbon nanotubes in the substrate 18 have on average an increased diameter and an increased bulk density at the end of the process since further grapheme-like layers have been formed around the individual carbon nanotubes due to the graphitic deposition. The conduit 16 can have a lock through which the starting material can be conveyed at the beginning of the process and the product can be conveyed at the end of the process. Here, gas exchange with the fluidized-bed reactor can take place. A lock is provided, in particular, for batchwise operation. However, a continuous or pseudo-continuous mode of operation is also possible.

Examples of suitable process conditions are described below in connection with the description of experimental results.

FIG. 2 shows a second illustrative embodiment of the process using a rotary tube reactor. The rotary tube reactor 32 has a tube 34 whose longitudinal axis 38 is inclined by a small angle α of, for example, from 1 to 5° relative to the horizontal base 36. The tube 34 can be rotated about its longitudinal axis 38 by means of a drive provided for this purpose (arrow 40).

At the beginning of the process, a substrate 42 composed of carbon nanotubes is introduced as starting material into the tube 34 (arrow 44) and applied with a bulk density of, for example, from 20 to 450 kg/m³ to the inner wall of the tube. The tube 34 is set into rotation by means of the drive so that the substrate 42 in the tube 34 is then present in an agitated bed 45. The substrate 42 is mixed well in this way during the process. Furthermore, good heat equilibration is obtained within the substrate.

A process temperature in the range from 950° C. to 1300° C., in particular 1000° C., is set within the tube 34, in particular within the substrate 42, by heating means which are provided (not shown).

From one end of the tube 34, a carbon-containing precursor such as ethylene or benzene is introduced into the tube 34 (arrow 46). The precursor can, for example, be introduced either alone or together with a process gas such as nitrogen into the tube. In the agitated bed of the rotary tube reactor 32, the precursor reacts under appropriately set process conditions so that carbon is graphitically deposited on the carbon nanotubes and the substrate 42. Excess precursor material or a process gas transporting the precursor material can exit again from the tube 34 at the other end (arrow 48). As an alternative, the process gas together with the carbon-containing precursor material can also be conveyed in the same direction as the substrate.

After the end of the process, the process product, i.e. the carbon nanotubes in substrate 42 which have been altered by the deposition of graphitic carbon, can be taken from the tube 34 (arrow 50). The carbon nanotubes present in the substrate at the end of the process have an increased diameter since the graphitic deposition of carbon has led to formation of further graphene-like layers around the individual carbon nanotubes.

FIGS. 3a-3e show illustrative embodiments of carbon nanotubes according to the invention which can, in particular, be produced by the process of the invention.

FIG. 3a shows a first carbon nanotube 60 in schematic isometric projection. The carbon nanotube 60 has a first inner graphene-like layer 64 and a second outer graphene-like layer 62. The first and second graphene-like layers 62, 64 each have a tubular structure. While the first graphene-like layer 64 is undoped, the second graphene-like layer 62 is doped with nitrogen. Nitrogen atoms are thus present at carbon lattice sites in the graphene structure of the second layer 62.

FIG. 3b shows a further carbon nanotube 70 in cross section, with a first layer 72, a second layer 74 and a third layer 76. The first and third layers 72 and 76 are undoped, while the second layer 74 is doped with nitrogen.

Carbon nanotubes as are shown in FIGS. 3a and 3b can be produced by the process of the invention. In the case of the carbon nanotube 60 in FIG. 3a, the nitrogen-doped second layer 62 is for this purpose deposited onto a carbon nanotube which is initially charged in the substrate and originally consists only of the first layer 64 by introduction of a carbon- and nitrogen-containing precursor, for example pyridine, into the moving bed during the process. If only a carbon-containing precursor is introduced into the moving bed in an optional further step, a third undoped graphene-like layer can subsequently be deposited, so that the structure shown in FIG. 3b is obtained.

FIG. 3c shows a further carbon nanotube 80 in cross section having a rolled structure (roll structure) in which a single graphene layer is rolled up so as to give a first inner layer 82 and an outer second layer 84. The inner layer 82 is doped with silicon, while the outer layer 84 is undoped. The carbon nanotube 80 can be produced by means of the process of the invention by a second undoped graphene-like layer 84 composed of carbon being applied onto a carbon nanotube which has a rolled structure consisting of a silicon-doped, graphene-like layer and has been initially charged in the substrate by introduction of a carbon-containing precursor into the agitated bed. In the illustrative embodiment depicted, the layer deposited in the process has been joined directly onto the original graphene layer, so that the impression of a continuous rolled graphene layer is given.

FIG. 3d shows a further carbon nanotube 90 in cross section which has a first inner layer 92 in the form of a rolled structure and an outer layer 94 having a tubular structure. The inner layer 92 is undoped while the outer layer 94 is doped with nitrogen. This carbon nanotube can be produced by means of the process described by the tubular, nitrogen-doped graphene-like second layer 94 being applied to a carbon nanotube having a rolled structure in the substrate by introduction of a carbon- and nitrogen-containing precursor into the agitated bed.

FIG. 3e shows a further carbon nanotube 100 in cross section which has a scroll structure on the inside having three graphene-like layers 102a-102c and an outer rolled structure 104. The layers of the scroll structure 102a-102c are undoped, while the outer layer 104 is doped with nitrogen. The carbon nanotube 100 can be produced by means of the process described by the further, rolled doped layer 104 being applied to a carbon nanotube having a scroll structure in the substrate by introduction of a carbon- and nitrogen-containing precursor into the agitated bed of the reactor.

FIG. 4 shows a schematic depiction of a graphene-like layer. In a graphene-like layer 120, the carbon atoms 122 are arranged in a characteristic hexagonal crystal structure having a biatomic basis, which gives a honeycomb-like arrangement of the carbon atoms 122. When a graphene-like layer is doped, a proportion of foreign atoms 24 is deliberately introduced into the graphene layer 120. The foreign atoms can be located at carbon lattice sites (124a) and thus in each case replace a carbon atom. Doping of the graphene-like layer 120 with foreign atoms enables the properties of the layer, in particular the electrical properties, to be altered in a targeted manner. Targeted doping of individual layers of a carbon nanotube thus allows the desired properties of the carbon nanotubes to be set.

FIG. 5 shows a schematic depiction of a further illustrative embodiment of the process of the invention. In the process 130, a substrate composed of carbon nanotubes is initially charged in an agitated bed of a reactor in a first step 132. In a second step 134, a carbon-containing precursor is introduced into the agitated bed. In a third step 136, the precursor reacts in the agitated bed under suitable process conditions which bring about graphitic deposition of carbon on the carbon nanotubes of the substrate. In a fourth step 138, the carbon nanotubes are discharged from the reactor. These carbon nanotubes discharged as process product differ from the carbon nanotubes initially charged as process starting material in that additional graphene-like layers have been deposited at least on part of the carbon nanotubes.

In the following, specific illustrative embodiments for carrying out the process of the invention and also the results of experiments carried out are presented.

### Experimental Procedure

The experiments were carried out using a fused silica fluidized-bed reactor having a fused silica tube having an internal diameter of 5 cm. As starting substrate, carbon nanotubes of the type Baytubes® C 150 P were used (unless indicated otherwise). These carbon nanotubes were (unless indicated otherwise) cleaned with acid in order to largely remove catalyst residues.

In each experiment, about 30 g of carbon nanotubes (initial weight) were (unless indicated otherwise) initially charged as substrate in the reactor and heated to the desired deposition temperature in a gas stream of nitrogen and hydrogen (for example about 2 l/min of nitrogen and about 6 l/min of hydrogen). The desired precursor was then transported through the initially charged bed. Liquid precursors were for this purpose conveyed into a prevaporizer by means of an injection pump and transported by the nitrogen gas stream through the initially charged bed. Gaseous precursors were introduced directly into the nitrogen gas stream and thus transported through the initially charged bed. After the end of the process, the carbon nanotubes were taken from the reactor again.

The amount of the substance deposited was determined by reweighing. The yield, i.e. the relative increase in weight of the substrate, was calculated from the ratio of the final weight to the initial weight.

The quality of the carbon nanotube powder was examined under a transmission electron microscope (TEM) after carrying out the process. In addition, the diameter distribution of the carbon nanotubes was determined under the TEM.

Furthermore, the quality of the deposited layers was examined by means of optical Raman measurements on the carbon nanotube powder. For this purpose, the relative signal intensities for the sp³-covalent carbon-carbon bonds and for the sp²-covalent carbon-carbon bonds were determined from the Raman spectrum and their ratio was calculated. The sp²-covalent bonds correspond to the bonding type in graphite and graphene and therefore demonstrate a graphene-like structure of the layers. On the other hand, the sp³-covalent bonds correspond to the bonding type in diamond and in the case of the carbon nanotubes indicate the presence of amorphous carbon. A small sp³/sp² ratio is therefore an indication that the carbon was deposited graphitcally.

It should be noted that the results of the Raman measurements do not give absolute ratios of sp³- and sp²-bonds. The relative comparison with the comparative examples and the starting material, i.e. the substrate initially charged, is decisive.

When foreign atom-containing precursors such as nitrogen- or silicon-containing precursors were used, the foreign atom concentration in the product was also determined by means of X-ray photoelectron spectroscopy.

### Results of the Experiments:

Various experiments (A-N) were carried out according to the above experimental description. In experiments A and B, carbon-containing precursors were used for depositing undoped graphitic layers. Furthermore, experiments using the aromatic nitrogen- and carbon-containing precursor pyridine (experiments C-H) and also using the silicon- and carbon-containing precursor C₆H₁₉NSi₂ (experiment I), using an unsaturated nitrogen- and carbon-containing precursor acrylonitrile (experiment J) and using a heterocyclic, substituted nitrogen- and carbon-containing precursor imidazole (experiment K) for deposition of nitrogen- or silicon-doped layers were carried out. Experiments L and M serve as comparative experiments using the precursors hydrogen and nitrogen. Furthermore, a comparative experiment N using graphite instead of carbon nanotubes as substrate was carried out.

The experimental parameters for the individual experiments and also the results of the quality studies are summarized in tables 1 and 2 below:

TABLE 1

| | A | B | C | D | E | F | G (1) | H (2) |
|---|---|---|---|---|---|---|---|---|
| Precursor | Benzene | Ethylene | Pyridine | Pyridine | Pyridine | Pyridine | Pyridine | Pyridine |
| Bulk density [kg/m³] | 336 | 329 | 425 | 283 | 277 | 233 | 253.6 | 233.9 |
| Temperature [° C.] | 1000 | 1000 | 1000 | 950 | 900 | 850 | 1000 | 1000 |
| Process gas stream N₂ [l/min] | 2 | — | 2 | 2 | 2 | 2 | 2 | 2 |
| Process gas stream H₂ [l/min] | 6.2 | 6.2 | 6 | 6 | 6 | 6 | 6 | 6 |
| Precursor flow (gas) [l/min] | 1 | 3 | 1 | 1 | 1 | 1 | 1 | 1 |
| Total amount of precursor [g] | 34.8 | 34.8 | 34.8 | 34.8 | 34.8 | 34.8 | 34.8 | 34.8 |
| Time [min.] | 10 | 10 | 10 | 10 | 10 | 10 | 10 | 10 |
| Yield [%] | 40 | 49 | 41 | 23 | 19 | 9 | 70 | 53 |
| TEM average value [nm] | 14 | 14.6 | 13.4 | 14.4 | 12.9 | 12.7 | 12 | 14.6 |
| TEM D90/D10 | 3.1 | 3.1 | 3 | 2.75 | 2.8 | | | 3.1 |
| Raman sp³/sp² | 0.89 | 1 | 0.78 | — | — | — | | |
| Foreign atom content [at. %] | | | N: 2.5 | N: 2.8 | N: 1.8 | N: 1.5 | | N: 2.5 |
| Result | ++ | ++ | ++ | + | | − | ++ | ++ |

TABLE 2

| | I | J | K | L | M | N (4) |
|---|---|---|---|---|---|---|
| Precursor | C₆H₁₂NSi₂ | Acrylonitrile | 1-Methylimidazole | H₂ | N₂ | Pyridine |
| | | | (3) | | | |
| Bulk density [kg/m³] | 302 | 238 | 276 | 217 | 215 | 343.3 |
| Temperature [° C.] | 1000 | 1000 | 1000 | 1000 | 1000 | 1000 |
| Process gas stream N₂ [l/min] | 4.5 | 1 | 1 | 2 | 7 | 1 |
| Process gas stream H₂ [l/min] | 0 | 2 | 2 | 6.2 | — | 2 |
| Precursor flow (gas) [l/min] | 0.082 | | | =H₂ | =N₂ | 0.3 |
| Total amount of precursor [g] | 11.9 | 2.5 | 8.1 | | | 34.8 |
| Time [min.] | 20 | 6 | 10 | 20 | 20 | 10 |
| Yield [%] | 30 | 13 | 25 | 0 | 0 | 0 |
| TEM average value [nm] | 12.7 | 11.1 | 12.6 | — | — | |
| TEM D90/D10 | 2.6 | 3.6 | 3.7 | | | |
| Raman sp³/sp² | | | | 1.05 | 1 | |
| Foreign atom content [at. %] | Si: 4.7 | N: 1.9 | N: 1.9 | | | |
| Result | + | ◯ | + | Comparison | Comparison | Comparison |

(1) For experiment G, 20 g of acid-cleaned carbon nanotubes of the type Nanocyl™ NC 7000 were used as substrate.
(2) For experiment H, uncleaned carbon nanotubes of the tube Baytubes® C 150 P were used as substrate.
(3) For experiment K, a mixture of 120 g of ethanol and 100 g of imidazole was used as precursor.
(4) For experiment N, graphite was used instead of carbon nanotubes as substrate.

In detail, the following data are shown in tables 1 and 2:
Precursor: The precursor used in the respective experiment.
Bulk density: Bulk density of the substrate in accordance with DIN EN ISO 60 in kg/m³ when weighed in.
Temperature: Process temperature in the fluidized bed in ° C.
Process gas stream N₂: Nitrogen gas flow through the fluidized bed in 1/min.
Process gas stream H₂: Hydrogen gas flow through the fluidized bed in 1/min.
Precursor inflow: Precursor gas flow through the fluidized bed in 1/min under standard conditions.
Total amount of precursor: Amount of precursor in g passed through the fluidized bed during the entire process.
Time: Duration of the process (from the beginning to the end of introduction of precursor) in minutes.
Yield: Weight increase of the substrate in percent, calculated from: 100%*(final weight−initial weight)/initial weight.
TEM average value: Statistical average of the diameter distribution of the carbon nanotubes determined under the TEM.
TEM D90/D10: Ratio of the diameter values D90 and D10.
Raman D/G: Ratio of the Raman signals for the D band and the G band.
Foreign atom content: Proportion of foreign atoms in at. % (element indicated in each case), determined by X-ray photoelectron spectroscopy (XPS).
Result: Result of the experiment in respect of efficient deposition of graphitic carbon on the carbon nanotubes; ++: very good; +: good; o: satisfactory; −: poor; comparison: comparative experiment.

The experiments L and M shown in table 2 are comparative experiments in which carbon-free precursors were used. No deposition of carbon on the carbon nanotubes therefore occurred in these experiments, so that the substrate also did not experience any increase in weight and the yield is accordingly zero. In the Raman measurements, a ratio of the Raman signals D/G of about 1 as in the case of the initial signal was measured for these carbon nanotubes. This comparative value demonstrates that the primarily graphitic growth of carbon is indicated in the Raman measurement by an sp³/sp² signal ratio of 1 or less than 1.

In the experiments A and B in table 1, carbon-containing precursors were used. The two experiments display a good yield of 40% and 49%, respectively. The ratio of the Raman signals is significantly below 1 for experiment C using benzene, so that the carbon was deposited essentially graphitically on carbon nanotubes. In the case of ethylene in experiment B, the ratio of the Raman signals under the experimental conditions indicated is 1. This indicates that the deposited carbon has the same graphitization as the carbon nanotubes of the starting material.

Experiments C to F are a series of experiments using pyridine as precursor, in which the process temperature was altered under otherwise essentially the same experimental conditions. At 1000° C. in experiment C, a good yield of 41% is achieved. The ratio of the Raman signals of 0.78 indicates predominant graphitic deposition of the carbon. As the process temperature decreases, a decrease in yield was observed until at a process temperature of 850° C. a yield of only 9% was achieved.

Since the precursor pyridine is a carbon- and nitrogen-containing precursor, the deposited graphene-like layers in experiments C to F are nitrogen-doped. Degrees of doping of from 1.5 at. % to 2.8 at. % were found by means of XPS studies.

In experiment G, acid-cleaned carbon nanotubes from another manufacturer, namely of the type Nanocyl™ NC 7000, were used as substrate. A very good yield of 70% could also be achieved using these carbon nanotubes.

In experiment H, carbon nanotubes of the type Baytubes® C 150 P were once again used as substrate but these had not been acid-washed so that the substrate contained a certain proportion of catalyst residues. A yield of 53% could likewise be achieved at a temperature of 1000° C. Experiment H therefore demonstrates that targeted thickness growth of carbon nanotubes can also succeed in the presence of catalyst residues when, for example, the process parameters are selected so that, in particular, the kinetic constant for thickness growth is greater than the kinetic constant for the length growth of the carbon nanotubes caused by catalyst constituents.

Experiment I was carried out using the precursor C₆H₁₉NSi₂ which contains silicon in addition to carbon and by means of which silicon-doped graphene-like layers can be deposited. In this experiment, an Si content in the product of 4.7 at. % and a yield of 30% were achieved.

Experiments J and K were again carried out using nitrogen-containing precursors, namely acrylonitrile and 1-methylimidazole, respectively. In experiment K, a mixture of 120 g of ethanol and 100 g of imidazole was used as precursor for this purpose.

The D90/D10 ratio of the diameter distribution of the carbon nanotubes determined under the TEM is shown in tables 1 and 2 for many of the abovementioned experiments. These values give information about the diameter distribution of the carbon nanotubes. Since graphitic deposition occurs preferentially on the carbon nanotubes having a relatively small diameter, the diameter distribution becomes narrower during the course of the process. In the case of the experiments carried out, the process time in the range from 6 to 20 minutes was still relatively short. In all experiments in which deposition occurs, this led to a diameter ratio of D90/D10 of significantly less than 4, while the starting material had a ratio of significantly above 4. Increasing the process time to at least 20 or at least 30 minutes enables the diameter distribution to become even narrower and the D90/D10 ratio to become correspondingly smaller.

Finally, experiment N in table 2 represents another comparative example in which graphite was used instead of carbon nanotubes as substrate. Despite the same precursor and the same process temperature as in experiment E, no deposition of carbon could be observed in this experiment, so that the yield is correspondingly 0%.

1.-16. (canceled)

17. A process for producing multi-wall carbon nanotubes which comprises the following steps:
initial charging of a substrate composed of carbon nanotubes in an agitated bed of a reactor,
introduction of a carbon-containing precursor into the agitated bed,
reaction of the precursor in the agitated bed under suitable process conditions which bring about graphitic deposition of carbon on the carbon nanotubes of the substrate,
discharge of the carbon nanotubes from the reactor.

18. The process as claimed in claim 17, wherein a process temperature in the range from 850° C. to 1300° C. is set for the process conditions which bring about graphitic deposition.

19. The process as claimed in claim 17, wherein a process temperature in the range from 950° C. to 1300° C., is set for the process conditions which bring about graphitic deposition.

20. The process as claimed in claim 17, wherein the proportion of catalysts which bring about length growth of carbon nanotubes in the agitated bed during the process is less than 5000 ppm.

21. The process as claimed in claim 17, wherein cleaned, in particular acid-cleaned, carbon nanotubes are used for the substrate.

22. The process as claimed in claim 17, wherein the process conditions, in particular temperature, pressure and/or gas composition in the reactor, are selected so that the ratio of the kinetic constant for thickness growth of the carbon nanotubes to the kinetic constant for the length growth of the carbon nanotubes caused by catalyst constituents is greater than 1.

23. The process as claimed in claim 17, wherein a fluidized bed of a fluidized-bed reactor is used as agitated bed.

24. The process as claimed in claim 17, wherein a precursor input into the reactor of from 0.0001 to 1 g per gram of substrate and per minute is set for the process conditions which bring about graphitic deposition.

25. The process as claimed in claim 17, wherein the carbon-containing precursor contains or consists of an optionally substituted aliphatic, cyclic, heterocyclic, aromatic and/or heteroaromatic compound or a mixture thereof.

26. The process as claimed in claim 24, wherein the aliphatic or heterocyclic compound is at least partially unsaturated.

27. The process as claimed in claim 17, wherein the carbon-containing precursor contains or consists of a compound comprising carbon and at least one heteroatom from the group consisting of nitrogen, boron, phosphorus and silicon; or the carbon-containing precursor contains at least two compounds of which at least one comprises carbon and at least one other of which comprises an element from the group consisting of nitrogen, boron, phosphorus and silicon.

28. A multi-wall carbon nanotube, in particular one which can be produced by a process as claimed in claim 17, having at least one first graphene-like layer and a second graphene-like layer, where the second layer is arranged outside the first layer in the cross section of the carbon nanotube,
wherein, one of the two layers has a first doping and the other of the two layers has a second, different doping or is undoped.

29. The carbon nanotube as claimed in claim 27, wherein one of the layers is doped with nitrogen, boron, phosphorus or silicon.

30. A carbon nanotube powder comprising carbon nanotubes as claimed in claim 27.

31. The carbon nanotube powder as claimed in claim 29, wherein the carbon nanotubes have an average diameter in the range from 3 to 100 nm.

32. The carbon nanotube powder as claimed in claim 29, wherein the carbon nanotubes have an average diameter in the range from 10 to 25 nm and the carbon nanotube powder has a diameter ratio D90/D10 of less than 3.

33. The carbon nanotube powder as claimed in claim 29, wherein the carbon nanotube powder has a diameter ratio D90/D10 of less than 4.

34. The carbon nanotube powder as claimed in claim 29, wherein the carbon nanotube powder has a bulk density of from 20 to 500 kg/m³.
